(19) United States
(12) Patent Application Publication
(10) Pub. No.: US 2013/0093145 A1
(43) Pub. Date: Apr. 18, 2013

(54) ELECTROSTATIC CHUCK

(71) Applicants: Hiroaki Hori, Fukuoka-ken (JP); Hiroki Matsui, Fukuoka-ken (JP); Ikuo Itakura, Fukuoka-ken (JP)

(72) Inventors: Hiroaki Hori, Fukuoka-ken (JP); Hiroki Matsui, Fukuoka-ken (JP); Ikuo Itakura, Fukuoka-ken (JP)

(73) Assignee: TOTO LTD., KITAKYUSHU-SHI, FUKUOKA (JP)

(21) Appl. No.: 13/635,736

(22) PCT Filed: Mar. 23, 2011
(86) PCT No.: PCT/JP2011/057038

§ 371 Date: Oct. 4, 2012

(30) Foreign Application Priority Data
Mar. 24, 2010 (JP) 2010-068981
Mar. 18, 2011 (JP) 2011-061739

(51) Int. Cl. H01L 21/683

(52) U.S. Cl. CPC H01L 21/6833
USPC 279/128

(57) ABSTRACT

An electrostatic chuck comprises a ceramic dielectric body having an electrode formed on a surface of the ceramic dielectric body; a ceramic substrate supporting the ceramic dielectric body; and a first bonding agent bonding the ceramic dielectric body to the ceramic substrate. The first bonding agent has a first major agent including an organic material, a first amorphous filler including an inorganic material, and a first spherical filler including an inorganic material. The first amorphous filler and the first spherical filler are dispersion-compounded in the first major agent. The first major agent, the first amorphous filler, and the first spherical filler are made of an electrically insulating material. An average diameter of the first spherical filler is greater than a maximum value of a minor axis of all of the first amorphous filler. A thickness of the first bonding agent is equal to or greater than the average diameter of the first spherical filler.

### TECHNICAL FIELD

The present invention relates to an electrostatic chuck.

### BACKGROUND ART

Electrostatic chucks are used as a means to clamp a processing target substrates during processing within a vacuum chamber. In recent years, processes that use high density plasma for the purpose of reducing takt time have become common. Therefore, methods for efficiently removing thermal flux from the high density plasma that inflows to the processing target substrate to outside the electrostatic chuck are required.

For example, constructions have been disclosed in which a temperature regulating plate is bonded to a bottom side of the electrostatic chuck (see Patent Literature 1, for example). In this structure, a ceramic plate with an electrode is adhered by a rubber, or the like, bonding agent to the top of a metal base substrate of a conductor. Thermal flux flowing into the processing target substrate passes through the electrostatic chuck and is conducted to the temperature regulating plate in which a cooling medium is circulated, and is discharged outside the electrostatic chuck by the cooling medium.

However, the thermal conductivity of the bonding agent configured with resin is one to two orders of magnitude less than the thermal conductivity of the ceramic plate and metal base substrate. Accordingly, the bonding agent can become a resistor to heat. Therefore, the bonding agent needs to be as thin as possible for the heat to efficiently exhaust. However, when thinned, the bonding agent can longer absorb misalignments between the metal base substrate and the ceramic plate caused by differences in the temperature or thermal expansion coefficient between the metal base substrate and the ceramic plate, and the adhesive strength is reduced.

As a solution to this, a structure is proposed in which a thermally conductive filler is blended and dispersed into the bonding agent to raise the thermal conductivity of the bonding agent (for example, see Patent Literature 2).

### CITATION LIST

### Patent Literature

[PLT 1]

Japanese Unexamined Patent Application Publication No. 63-283037

[PLT 2]

Japanese Unexamined Patent Application Publication No. 02-027748

### SUMMARY OF INVENTION

### Technical Problem

However, when the ceramic dielectric body and the ceramic substrate, which are components that constitute the electrostatic chuck, are bonded by a bonding agent in which thermally conductive filler has been blended and dispersed, cracking can occur on ceramic dielectric body side. This is because the thermally conductive filler blended and dispersed in the bonding agent is amorphous and has a variable particle size (distribution).

For example, the ceramic dielectric body and the ceramic substrate are bonded by interposing the bonding agent therebetween and curing the bonding agent by hot pressing. Here, if the amorphous filler has a variable particle size, a thickness of the bonding agent will be determined by the particle size of the amorphous filler.

In particular, during hot press curing of an amorphous filler including large particles, pressure will concentrated in the amorphous filler and excessive stress will be applied to the ceramic dielectric body in contact with the amorphous filler. As a result, cracks may be generated on the ceramic dielectric body side.

The problem of this invention is to provide an electrostatic chuck in which the bonding agent is thin and has high thermal conductivity and in which cracking is unlikely to occur in the components that constitute the electrostatic chuck.

### Solution to Problem

The first invention relates to an electrostatic chuck that includes a ceramic dielectric body having an electrode formed on a surface of the ceramic dielectric body, a ceramic substrate supporting the ceramic dielectric body, and a first bonding agent bonding the ceramic dielectric body to the ceramic substrate. The first bonding agent has a first major agent including an organic material, a first amorphous filler including an inorganic material, and a first spherical filler including an inorganic material. The first amorphous filler and the first spherical filler are dispersion-compounded in the first major agent. The first major agent, the first amorphous filler, and the first spherical filler are made of an electrically insulating material. An average diameter of the first spherical filler is greater than a maximum value of a minor axis of all of the first amorphous filler. A thickness of the first bonding agent is equal to or greater than the average diameter of the first spherical filler.

Electrical insulation properties are secured around the electrode by setting the ceramic substrate and the electrode so as to oppose each other and bonding the two to form a single entity using a first bonding agent. Here, since main component of the material of the ceramic substrate and the ceramic dielectric body is a ceramic sintered body, durability and reliability of the electrostatic chuck are superior to electrostatic chucks made of resin.

Further, because the first spherical filler and the first amorphous filler are inorganic materials, the respective sizes thereof (for example, the diameter) are easily controlled. Therefore, blending and dispersing of the first bonding agent with the first major agent is easily performed. Because the first major agent of the first bonding agent, the first amorphous filler, and the first spherical filler are electrically insulating materials, the electrical insulation properties around the electrode can be secured.

Further, the average diameter of the first spherical filler is greater than the maximum value of a minor axis of all of the first amorphous filler. Therefore, the thickness of the first bonding agent can be controlled using the first spherical filler to be either equal to the average diameter of the first spherical filler or greater than the average diameter. Consequently, during hot press curing of the first bonding agent, local stresses are not applied to ceramic dielectric body by the amorphous filler and the occurrence of cracking of the ceramic dielectric body can be prevented.

The second invention is the electrostatic chuck according to the first invention, wherein the average diameter of the first spherical filler is at least 10 μm greater than the maximum value of the minor axis of the first amorphous filler.

When the average diameter of the first spherical filler is at least 10 μm greater than the maximum value of the minor axis of the first amorphous filler, the thickness of the first bonding agent can be controlled by the diameter of the first spherical filler and not by the size of the first amorphous filler when hot press curing the first bonding agent. In other words, at the time of hot press curing, it is less likely that local stress will be applied to the ceramic substrate and the ceramic dielectric body by the first amorphous filler. Consequently, the crack generation of the ceramic dielectric body can be prevented.

Further, when the variation in the flatness and thickness of the ceramic substrate and the ceramic dielectric body positioned above and below the first bonding agent is not more than 10 μm (for example, 5 μm), the surface irregularity of the ceramic substrate and the ceramic dielectric body can be absorbed (mitigated) by the first bonding agent through setting the average diameter of the first spherical filler to be at least 10 μm greater than the maximum value of the minor axis of the first amorphous filler.

Further, when the variation in the flatness and thickness of the electrode provided on the surface of the ceramic substrate is not more than 10 μm (for example, 5 μm), the surface irregularity of the electrode can be absorbed (mitigated) by the first bonding agent through setting the average diameter of the first spherical filler to be at least 10 μm greater than the maximum value of the minor axis of the first amorphous filler. In this case, the first spherical filler will touch the surface of the electrode without contacting the ceramic substrate or the ceramic dielectric body. Therefore, crack generation in the ceramic dielectric body can be suppressed.

The third invention is the electrostatic chuck according to the first invention, wherein the volume concentration (vol %) of the first spherical filler is greater than 0.025 vol % and less than 42.0 vol % with respect to the volume of the first bonding agent containing the first amorphous filler.

When the volume concentration (vol %) of the first spherical filler is set greater than 0.025 vol % of the volume of the first bonding agent containing the first amorphous filler, dispersion within the first bonding agent of the first spherical filler is favorable. In other words, the first spherical filler can be diffused evenly in the first bonding agent. Hence, the thickness of the first bonding agent is set to be equal to or greater than the first spherical filler average diameter. This means that the first amorphous filler is less likely to apply local stress to the ceramic dielectric body when hot press curing the first bonding agent. As a result, crack generation in the ceramic dielectric body can be suppressed.

Further, by making the volume concentration (vol %) thereof less than 42.0 vol %, the first spherical filler can be sufficiently stirred into the first bonding agent containing the first amorphous filler. In other words, as long as the volume concentration (vol %) is less than 42.0 vol %, dispersion of the first spherical filler will be uniform within the first bonding agent in which the first amorphous filler is contained.

The fourth invention is the electrostatic chuck according to the first invention, wherein the material of the first major agent of the first bonding agent is any one of a silicon resin, an epoxy resin, or a fluororesin.

The characteristics of the first major agents after the major agent has been cured can be appropriately selected by changing the material of the first major agent of first bonding agent. For example, if flexibility is desired in the first bonding agent after curing, then a silicon resin or a fluororesin with a comparatively low hardness is used. If rigidity is desired in the first bonding agent after curing, then an epoxy resin with a comparatively high hardness is used. If plasma durability is desired in the first bonding agent after curing, then a fluororesin is used.

The fifth invention is the electrostatic chuck according to the first invention, wherein the thermal conductivity of the first spherical filler and the first amorphous filler is greater than the thermal conductivity of the first major agent of the first bonding agent.

Because the thermal conductivity of the first spherical filler and the first amorphous filler is greater than the first major agent of the first bonding agent, the thermal conductivity of the first bonding agent is greater than a bonding agent with only the major agent, and cooling performance is thus improved.

The sixth invention is the electrostatic chuck of the first invention, wherein the material of the first spherical filler and the material of the first amorphous filler are different.

The purpose of adding the first spherical filler to the first bonding agent is to promote uniformity in the thickness of the first bonding agent and to disperse the stress applied to the ceramic dielectric body. The purpose of adding the first amorphous filler to the first bonding agent is to increase the thermal conductivity of the first bonding agent and to promote uniformity in the thermal conductivity.

Thus, selecting materials better suited to these purposes allows a better performance to be obtained.

The seventh invention is the electrostatic chuck according to the fifth invention, wherein the thermal conductivity of the first spherical filler is less than the thermal conductivity of the first amorphous filler.

For example, when the first spherical filler contacts the ceramic substrate, the ceramic dielectric body, or the electrode provided on the ceramic dielectric body, the difference between the thermal conductivity of the contacting portion and other portions is reduced. Accordingly, uniformity can be promoted in the in-plane temperature distribution of the ceramic dielectric body.

The eighth invention is the electrostatic chuck according to the seventh invention, wherein the thermal conductivity of the first spherical filler is equal to or less than the thermal conductivity of a mixture of the first amorphous filler and the first major agent.

By making the thermal conductivity of the first spherical filler equal to or less than the thermal conductivity of the mixture of the first amorphous filler and the first major agent, the thermal conductivity within the first bonding agent becomes more uniform, and generation of temperature singularities, so-called hot spots and cold spots, during thermal conduction within the first bonding agent can be suppressed.

The ninth invention is the electrostatic chuck according to the eighth invention, wherein the thermal conductivity of the first spherical filler is in a range of 0.4 times to 1.0 times the thermal conductivity of the mixture of the first amorphous filler and the first major agent.

By setting the thermal conductivity of the first spherical filler within a range of 0.4 times to 1.0 times the thermal conductivity of the mixture of the first amorphous filler and the first major agent, the thermal conductivity within the first bonding agent can be made more uniform. As a result, the generation of temperature singularities, so-called hot spots and cold spots, during thermal conduction within the first bonding agent can be suppressed.

When the thermal conductivity of the first spherical filler is less than 0.4 times the thermal conductivity of the mixture of the first amorphous filler and the first major agent, the thermal conductivity of the first spherical filler and the first bonding agent in the vicinity thereof becomes low. As a result, hot spots are generated in the first bonding agent when a thermal flux is applied to the ceramic dielectric body and the processing target substrate, which is the adhered body.

When the thermal conductivity of the first spherical filler is greater than 1.0 times the thermal conductivity of the mixture of the first amorphous filler and the first major agent, the thermal conductivity of the first spherical filler and the first bonding agent in the vicinity thereof becomes high. As a result, cold spots are generated in the first bonding agent when a thermal flux is applied to the ceramic dielectric body and the processing target substrate, which is the adhered body.

The tenth invention is the electrostatic chuck according to the first invention, wherein the thickness of the ceramic dielectric body is equal to or less than the thickness of the ceramic substrate.

Making the thickness of the ceramic dielectric body equal to or greater than the thickness of the ceramic substrate allows the ceramic dielectric body to be reliably and fixedly held on the ceramic substrate. Accordingly, when the ceramic dielectric body and the ceramic substrate have been bonded, crack generation in the ceramic dielectric body can be prevented even when the ceramic dielectric body is processed. Moreover, the flatness and uniformity of the thickness of the ceramic dielectric body after processing is favorable.

The eleventh invention is the electrostatic chuck according to the tenth invention, wherein a Vickers hardness of the first spherical filler is less than a Vickers hardness of the ceramic dielectric body.

Due to the first spherical filler, the thickness of the first bonding agent is controlled to be equal to or greater than the average diameter of the first spherical filler. When the Vickers hardness of the first spherical filler is set to be less than the Vickers hardness of the ceramic dielectric body, if any individual particles greater than the average diameter are dispersed and blended into the first spherical filler, these particles are destroyed in preference to the ceramic dielectric body during hot press curing of the first bonding agent. Hence, local stresses are not applied to the ceramic dielectric body, and crack generation in the ceramic dielectric body can be prevented.

The twelfth invention is the electrostatic chuck according to the first invention further including: a temperature regulating unit bonded to the ceramic substrate; and a second bonding agent that bonds the ceramic substrate to the temperature regulating unit, wherein the second bonding agent includes a second major agent that contains an organic material, a second amorphous filler that includes an inorganic material, and a second spherical filler that includes an inorganic material; the second amorphous filler and the second spherical filler are dispersion-compounded into the second major agent; the second major agent, the second amorphous filler, and the second spherical filler are made of electrically insulating material; an average diameter of the second spherical filler is greater than the maximum value of a minor axis of all of the first amorphous filler; a thickness of the second bonding agent is equal to or greater than the average diameter of the second spherical filler, and an average diameter of the second spherical filler is greater than the average diameter of the first spherical filler.

Since the average diameter of the second spherical filler is greater than the maximum value of a minor axis of all of the second amorphous filler, as a result of the second spherical filler, the thickness of the second bonding agent can be controlled to be either equal to or greater than the average diameter of the second spherical filler. Accordingly, local stress is not applied to the ceramic substrate by the amorphous filler during hot press curing of the second bonding agent, and crack generation in the ceramic substrate can be prevented.

Further, rigidity of the ceramic substrate is improved by bonding the temperature regulating unit (temperature regulating plate) to the ceramic substrate. Also, when the ceramic dielectric body is processed, crack generation in the ceramic dielectric body can be prevented. As a result of the dispersion-compounding of the spherical filler in the second bonding agent, the ceramic substrate can be fixedly held with second bonding agent of uniform thickness. Consequently, crack generation in the ceramic dielectric body can be prevented even when the ceramic dielectric body is processed.

Further, when the temperature regulating unit is made of metal, the linear expansion coefficient of the temperature regulating unit will be greater than the linear expansion coefficient of the ceramic substrate. By setting the average diameter of second spherical filler to be greater than the average diameter of the first spherical filler, the thickness of the second bonding agent is caused to be greater than the thickness of the first bonding agent. Accordingly, the difference in thermal expansion and contraction between the ceramic substrate and the temperature regulating unit is easily absorbed in the second bonding agent, and it becomes less likely that deformation of the ceramic substrate or separation of the ceramic substrate and temperature regulating unit will occur.

### Advantageous Effects of Invention

According to this invention, an electrostatic chuck is realized in which the bonding agent is thin and has high thermal conductivity and in which cracking is unlikely to occur.

### BRIEF DESCRIPTION OF DRAWINGS

[FIG. 1]

FIGS. 1A to 1C are schematic cross-sectional views of a relevant part of an electrostatic chuck, FIG. 1B is a magnified view of the portion indicated by arrow A in FIG. 1A, and FIG. 1C is a magnified view of the portion indicated by arrow B in FIG. 1B.

[FIG. 2]

FIGS. 2A and 2B are schematic views of when crack generation has occurred in the ceramic dielectric body.

[FIG. 3]

FIGS. 3A and 3B are cross-sectional SEM images of the bonding agents, FIG. 3A being a cross-sectional SEM image of the bonding agent in which the spherical filler and the amorphous filler are blended and dispersed, and FIG. 3B being a cross-sectional SEM image of the bonding agent in which the amorphous filler is blended and dispersed.

[FIG. 4]

FIG. 4 is a diagram for describing the minor axis of the amorphous filler.

[FIG. 5]

FIGS. 5A and 5B are diagrams describing one example of effects of the electrostatic chuck.

### DESCRIPTION OF EMBODIMENTS

Detailed embodiments will be described hereinafter with reference to drawings. The embodiment described below also includes a description of means for resolving the problem given above.

First, descriptions will be given of terms used in the embodiment of the present invention.

### (Ceramic Substrate, Ceramic Dielectric Body)

The ceramic substrate (also called a support substrate or intermediate substrate) is a stage for supporting the ceramic dielectric body. The ceramic dielectric body is a stage for mounting the processing target substrate. The ceramic substrate and the ceramic dielectric body are designed to use a ceramic sintered body as a material and are of uniform thickness. The flatness of the major surfaces of the ceramic substrate and the ceramic dielectric body is designed to be within a predetermined range. When each thickness is uniform and appropriate flatness is secured in each major surface of the ceramic substrate and the ceramic dielectric body, it is less likely that local stresses will be applied to the ceramic substrate and ceramic dielectric body during hot press curing. Further, the thickness of the bonding agent interposed between the ceramic substrate and the ceramic dielectric body can be controlled by the average diameter of the spherical filler.

The ceramic substrate has a diameter of approximately 300 mm and a thickness of approximately 2 to 3 mm. The ceramic dielectric body has a diameter of approximately 300 mm and a thickness of approximately 1 mm. The flatness of the ceramic substrate and the ceramic dielectric body is not more than 20 μm. A variation in the thickness of the ceramic substrate and the ceramic dielectric body is not more than 20 μm. In addition, the flatness and the variation in the thickness of the ceramic substrate and the ceramic dielectric body are preferably not more than 10 μm.

### (Bonding Agent)

The bonding agents are for bonding the ceramic substrate and the ceramic dielectric body, and bonding the ceramic substrate and the temperature regulating unit. For the bonding agent (also referred to as an adhesive and bonding layer), an organic material is preferable due to the low heat curing temperature and flexibility after curing of such materials. The material of the major agent of the bonding agent is any of silicon resin, epoxy resin, or fluororesin. For example, a silicon resin bonding agent or a fluororesin bonding agent having a comparatively low hardness may be used as the bonding agent. In the case of a silicon resin bonding agent, a two-liquid added type is more preferred. When using a two-liquid added type of the silicon resin bonding agent, the curing properties are favorable in the deep parts of the bonding agent, and the occurrence of gas pockets (voids) when curing is less likely than with a deoximation type and a dealcoholization type. Further, the curing temperature is lower with a two-liquid added type than with a one-liquid added type. By this, the stress generated in the bonding agent becomes smaller. Note that when high rigidity is desired in the bonding agent, an epoxy resin bonding agent or a fluororesin resin is used. Further, when high anti-plasma durability is desired in the bonding agent, a fluororesin bonding agent is used.

### (Amorphous Filler)

The amorphous filler is an additive for increasing the thermal conductivity of the bonding agent. Therefore, it is preferred that the form thereof be amorphous. The thermal conductivity is greater with a bonding agent that in which the major agent of the bonding agent and the amorphous filler are blended and dispersed compared to a bonding agent with only the major agent. For example, in contrast to a thermal conductivity of approximately 0.2 (W/mK) with the major agent elemental substance of the bonding agent, the thermal conductivity increases to a range of 0.8 to 1.7 (W/mK) when the silicon major agent is blended with an alumina amorphous filler. Further, an amorphous filler with an average diameter of no less than two types may be blended and dispersed in order to improve the filling rate of the major agent of the bonding agent. The material of the amorphous filler is an inorganic material. Specifically, the material corresponds to, for example, alumina, aluminum nitride, silica, and the like. The amorphous filler top surface may be treated in order to increase the affinity between the amorphous filler and the major agent of the bonding agent. The weight concentration of the amorphous filler is between 70 to 80 (wt %) relative to the major agent of the bonding agent.

### (Spherical Filler)

The spherical filler is an additive for controlling the thickness of the bonding agent. To allow accurate control of the thickness of the bonding agent, it is preferable that the filler has a spherical form. The material of the spherical filler is an inorganic material. Note, however, that the material of the spherical filler and the material of the amorphous filler are different. The material of the spherical filler corresponds to, for example, glass or the like. When the filler shape is spherical, blending and dispersing into the bonding agent becomes easier. In addition, even when an amorphous filler exists between spherical filler and the ceramic substrate or between the spherical filler and the ceramic dielectric body at bonding, the spherical form of the filler makes it easy for the amorphous filler to move within the bonding agent. It is preferable that the form of the spherical filler closely resembles a true sphere and that the diameter distribution is narrow. When this is the case, the thickness of the bonding agent can be controlled more accurately. Further, for control of the thickness of the bonding agent, it is preferable that the diameter of the spherical filler is greater than that of the amorphous filler.

The term “spherical” of the spherical filler refers to not only a true sphere but shapes that approximate a true sphere. In other words, not less than 90% of the grains are within a form factor range of 1.0 to 1.4. Here, the form factor is calculated from the average value of the ratio of the major axis of several hundred (for example, 200) grains, magnified and observed by a microscope, to the minor axis that is orthogonal to the major axis. Accordingly, the form factor is 1.0 only if the grains are perfectly spherical, and moves further away from 1 as the grains become less spherical. Further, the term amorphous referred to here refers to that which exceeds a form factor of 1.4.

Note that the grain diameter distribution width of the spherical filler is narrower than the grain diameter distribution width of the amorphous filler. In other words, the variation in the grain diameter of the spherical filler is less than the variation in the grain diameter of the amorphous filler. Here, the grain diameter distribution width is defined by using, for example, the half value width of the grain diameter distribution, quarter value width of the grain diameter distribution, a standard deviation, or the like.

The purpose of adding the spherical filler to the bonding agent is to promote uniformity in the thickness of the bonding agent and to disperse the stress applied to the ceramic dielectric body. Meanwhile, the purpose of adding the amorphous filler to the bonding agent is to increase the thermal conductivity of the bonding agent and to promote uniformity in the thermal conductivity. Thus, selecting a material that better fits these purposes allows a better performance to be obtained.

The diameter distribution of the first spherical filler is similar to the following distribution based on the JIS R6002 (test method for grains in abrasives for use with grind stones) screening test method.

The first spherical filler has a diameter distribution in which 10% diameter and 90% diameter fall within no more than +/−10% of 50% diameter. Here, 90% diameter is a diameter of the spherical filler at which 90% remains on the mesh with a 63 μm mesh, a 10% diameter is a diameter of the spherical filler at which 10% remains on the mesh with a 77 μm mesh, and a 50% diameter is a diameter of the spherical filler at which 50% remains on the mesh with a 70 μm mesh. In this embodiment, 50% diameter is used as a target value for the first spherical filler.

### (Average Diameter)

The average diameter is a value that is the numerical value of the sum of all the spherical filler diameters divided by the number of all the spherical fillers.

### (Minor Axis)

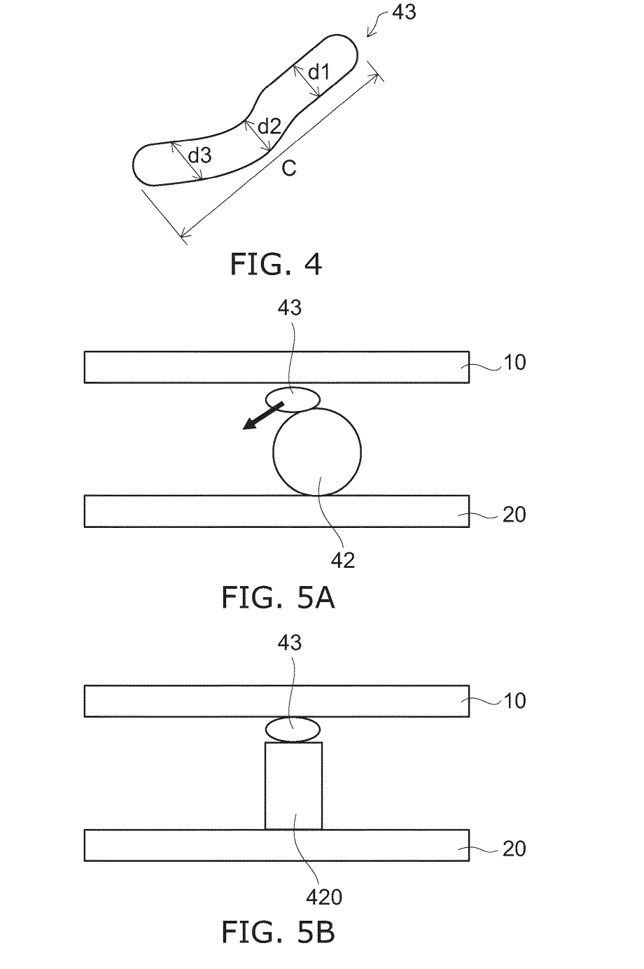

The minor axis is the length of the short direction that is orthogonal to the longitudinal direction of the amorphous filler (see FIG. 4). (Maximum Value of the minor axis)

The maximum value of the minor axis is the maximum minor axis value of a minor axis of all of the amorphous filler.

### (Vickers Hardness)

The Vickers hardness of the first spherical filler is preferably less than the Vickers hardness of the ceramic dielectric body.

As a result of the first spherical filler, the thickness of the first bonding agent is controlled to be equal to or greater than the average diameter of the first spherical filler. When the Vickers hardness of the first spherical filler is set to be less than the Vickers hardness of the ceramic dielectric body, if any individual particles greater than the average diameter are dispersed and blended into the first spherical filler, these particles are destroyed in preference to the ceramic dielectric layer during hot press curing of the first bonding agent. Therefore, crack generation in the ceramic dielectric body can be prevented without applying local stress to the ceramic dielectric body.

Here, the testing method of the Vickers hardness was implemented based on JIS R 1610. For the Vickers hardness test equipment, the instruments stipulated in JIS B 7725 and JIS B 7735 were used.

### (Thermal Conductivity)

The thermal conductivity of the first spherical filler is equal to or less than the thermal conductivity of the mixture of the first amorphous filler and the first major agent. More preferably, the thermal conductivity of the first spherical filler is set within a range of 0.4 times to 1.0 times the thermal conductivity of the mixture of the first amorphous filler and the first major agent. In such a range, the thermal conductivity within the first bonding agent becomes more uniform. As a result, the generation of temperature singularities, so-called hot spots and cold spots, during thermal conduction within the first bonding agent can be suppressed.

It is preferable that the thermal conductivity of the first spherical filler is in a range of 0.4 times to 1.0 times the thermal conductivity of the mixture of the first amorphous filler and the first major agent.

It is more preferable that the thermal conductivity within the first bonding agent is made uniform by setting the thermal conductivity of the first spherical filler within a range of 0.4 times to 1.0 times the thermal conductivity of the mixture of the first amorphous filler and the first major agent. As a result, the generation of temperature singularities, so-called hot spots and cold spots, during thermal conduction within the first bonding agent can be suppressed.

When the thermal conductivity of the first spherical filler is less than 0.4 times the thermal conductivity of the mixture of the first amorphous filler and the first major agent, the thermal conductivity of the first spherical filler and the first bonding agent in the vicinity thereof becomes low. As a result, hot spots are generated within the first bonding agent when a thermal flux is applied to the ceramic dielectric body and the processing target substrate, which is the adhered body.

When the thermal conductivity of the first spherical filler is greater than 1.0 times the thermal conductivity of the mixture of the first amorphous filler and the first major agent, the thermal conductivity of the first spherical filler and the first bonding agent in the vicinity thereof becomes high. As a result, cold spots are generated within the first bonding agent when a thermal flux is applied to the ceramic dielectric body and the processing target substrate, which is the adhered body.

When the material of the first spherical filler is glass, the thermal conductivity is in the range of 0.55 to 0.8 (W/mk). The thermal conductivity of the first spherical filler is set to be suitable with respect to the thermal conductivity (0.8 to 1.7 (W/mK)) of the mixture of a silicon major agent and an alumina amorphous filler.

Here, measurements of thermal conductivity of the spherical filler were implemented based on JIS R 1611. For the mixture of the major agent and the amorphous filler, measurements of thermal conductivity were implemented with a thermal wire probe using the QTM-D3 thermal conductivity meter made by Kyoto Electronics.

Next, a description will be provided of the configuration of the electrostatic chuck according to this embodiment. Content that duplicates the description of terms given above will be appropriately omitted.

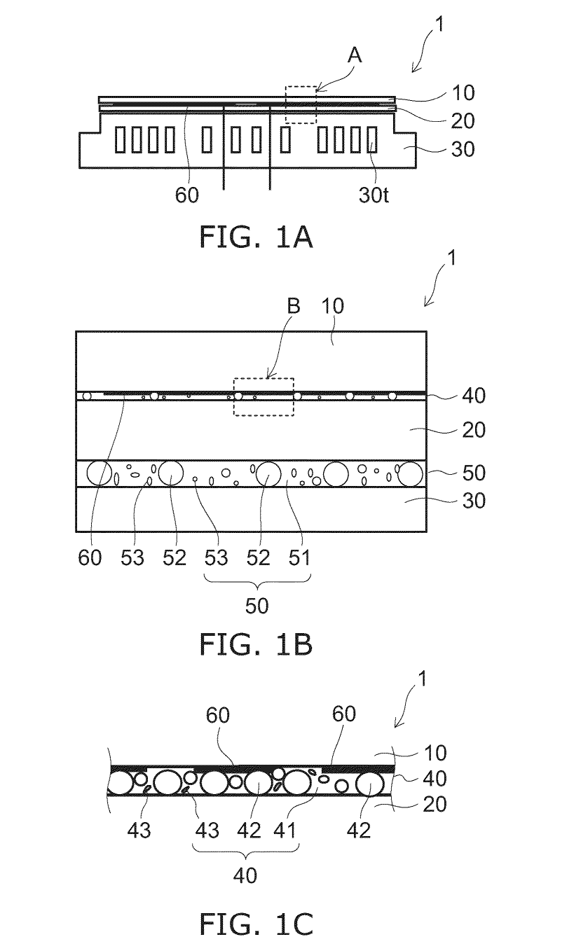

FIG. 1A is cross-sectional schematic views of a relevant part of an electrostatic chuck; FIG. 1B is a magnified view of the portion indicated by arrow A in FIG. 1A; and FIG. 1C is a magnified view of the portion indicated by arrow B in FIG. 1B.

First, a description will be given of an overview of an electrostatic chuck 1.

The electrostatic chuck 1 includes a ceramic dielectric body 10 having an electrode 60 formed on a surface thereof, a ceramic substrate 20 that supports the ceramic dielectric body 10 and a first bonding agent 40 that bonds the ceramic dielectric body 10 to the ceramic substrate 20.

The bonding agent 40 has a first major agent 41 that includes an organic material such as silicon, a first amorphous filler 43 that includes an inorganic material, and a first spherical filler 42 that includes an inorganic material. The first amorphous filler 43 and the first spherical filler 42 are dispersion-compounded in the first major agent 41. The first major agent 41, the first amorphous filler 43 and the first spherical filler 42 are electrically insulating materials, and the average diameter of the first spherical filler 42 is greater than the maximum value of a minor axis of all of the first amorphous filler 43. A thickness of the first bonding agent 40 is configured to be equal to or greater than the average diameter of the first spherical filler 42.

Further, the electrostatic chuck 1 includes a temperature regulating unit 30 that is bonded to the ceramic substrate 20, and a second bonding agent 50 that bonds the ceramic substrate 20 to the temperature regulating unit 30. The details of the bonding agent 50 will be described below.

A detailed description will be given of the electrostatic chuck 1.

As described above, the first bonding agent 40 is provided between the ceramic dielectric body 10 and the ceramic substrate 20, and the second bonding agent 50 is provided between the ceramic substrate 20 and the temperature regulating unit 30.

The ceramic dielectric body 10 is a Johnson-Rahbek material with a volume resistivity (at 20° C.) of 10⁹ to 10¹³ Ω·cm. A diameter thereof is 300 mm, and the thickness is 1 mm.

Vickers hardness of the ceramic dielectric body 10 is not less than 15 GPa.

The electrode 60 is selectively provided on a major surface (bottom face side) of the ceramic dielectric body 10. When a voltage is applied to the electrode 60, the ceramic dielectric body 10 is electrostatically charged. As a result, the processing target substrate can be electrostatically adhered to the ceramic dielectric body 10. The total area of the electrode 60 is between 70% and 80% of the area of the bottom face of the ceramic dielectric body 10. The thickness of the electrode 60 is 0.8 μm.

For the ceramic substrate 20, for example, the major component is high-purity alumina (purity of 99%), the diameter is 300 mm, and the thickness is 2 to 3 mm. The ceramic substrate 20 is a member for promoting electrical insulating properties between the electrode 60 and the temperature regulating unit 30. Further, the ceramic substrate 20 is a stage when processing the ceramic dielectric body 10. By using the ceramic substrate 20 as a stage for the ceramic dielectric body 10, flatness of the ceramic dielectric body 10 can be secured even when the ceramic dielectric body 10 is processed by grinding.

The major component of the temperature regulating unit 30 is, for example, aluminum (Al:A6061) or an alloy of aluminum and silicon carbide (SiC). In addition, a media path 30t is formed in the inner part on the temperature regulating unit 30 by low embossing. A medium for regulating temperature is circulated in the media path 30t. The diameter of the temperature regulating unit 30 is 320 mm, and the thickness is 40 mm.

The bonding agent 40 includes the major agent 41, the spherical filler 42, and the amorphous filler 43. The bonding agent 40 is formed by vacuum bonding, hot press curing, or the like, between the ceramic dielectric body 10 and the ceramic substrate 20. The spherical filler 42 and the amorphous filler 43 are blended and dispersed in the major agent 41. The concentration of the amorphous filler 43 is approximately 80 wt % of the bonding agent 40.

In the material of the bonding agent 40, the major agent 41 is silicon resin, the amorphous filler 43 is alumina particles, and the spherical filler 42 is soda lime glass. The thermal conductivity of the mixture of the major agent 41 and the amorphous filler 43 is 1.0 (W/mK), and the thermal conductivity of the spherical filler 42 is 0.7 W/mK. Further, the Vickers hardness of the spherical filler 42 is not more than 6 Gpa.

The average diameter of the spherical filler 42 is approximately 70 μm, and more specifically, the 90% diameter is 66.5 μm, the 50% diameter is 69.2 μm, and the 10% diameter is 71.8 μm.

The second bonding agent 50 has a second major agent 51 that includes an organic material, a second amorphous filler 53 that includes an inorganic material, and a second spherical filler 52 that includes an inorganic material. The second amorphous filler 53 and the second spherical filler 52 are dispersion-compounded in the second major agent 51. The second major agent 51, the second amorphous filler 53 and the second spherical filler 52 are electrically insulating materials. The average diameter of the second spherical filler 52 is greater than the maximum value of a minor axis of all of the second amorphous filler 53. A thickness of the second bonding agent 50 is equal to or greater than the average diameter of the second spherical filler 52. The average diameter of the second spherical filler 52 is configured to be greater than the average diameter of the first spherical filler 42. The bonding agent 50 is formed by vacuum bonding, hot press curing, or the like, between the ceramic substrate 20 and the temperature regulating unit 30. The spherical filler 52 having an average diameter of 100 to 330 μm (measured with a micrometer) and the amorphous filler 53 are blended and dispersed in the major agent 51. Interposing the bonding agent 50 between the ceramic substrate 20 and the temperature regulating unit 30 mitigates the difference in thermal contraction and expansion between the ceramic substrate 20 and the temperature regulating unit 30. As a result, deformation of the ceramic substrate 20 and separation of the ceramic substrate 20 and the temperature regulating unit 30 are less likely to occur. The concentration of the amorphous filler 53 is approximately 80 wt % of the bonding agent 50.

In the electrostatic chuck 1, electrical insulating properties are secured around the electrode 60 by having the ceramic substrate 20 oppose the ceramic dielectric body 10 with the electrode 60 formed thereon, and adhering these together with the bonding agent 40. Since a main component of the material of the ceramic substrate and the ceramic dielectric body is a ceramic sintered body, durability and reliability of the electrostatic chuck are superior to those of electrostatic chucks made of resin.

Since the spherical filler 42 and the amorphous filler 43 are made of an inorganic material, controlling the sizes (such as diameters) is easy, and blending and dispersion with the major agent 41 of the bonding agent 40 is simple. Because the major agent 41 of the bonding agent 40, the amorphous filler 43 and the spherical filler 42 are electrically insulating materials, electrical insulating properties can be secured around the electrode 60.

The average diameter of the spherical filler 42 that is blended and dispersed into the first bonding agent 40 is verified as follows.

First, Table 1 shows the thickness of the bonding agent 40 when the amorphous filler 43 is blended and dispersed into the major agent 41 without the spherical filler 42 being blended and dispersed. A total of 26 samples, No. 1 to 26, were prepared as measurement samples. The variation in the thickness of the bonding agent 40 was found for these samples. Each sample was an arrangement configured by adhering together ceramic plates having a diameter of 300 mm using hot press curing with the bonding agent 40 in which only the amorphous filler 43 was blended and dispersed into the major agent 41.

There were a total of 17 measurement points for each sample with 8 locations being on the peripheral part, 8 locations in the intermediate part, and one location in the center part. From these locations, the thickness of the thickest part, the thickness of the thinnest part, and the average thickness were found for each sample.

As shown in Table 1, the thickest part of the bonding agent 40 varied in a range of 22 to 60 μm. The thinnest part of the bonding agent 40 varied in a range of 3 to 46 μm. In other words, when the longitudinal direction of the amorphous filler 43 is not parallel to the major surface of the ceramic dielectric body 10, the minor axis of the amorphous filler 43 can be estimated to vary in the range of 3 to 60 μm. In this case, the maximum value of the minor axis of the amorphous filler 43 can be estimated to be 60 μm.

Note that when the longitudinal direction of the amorphous filler 43 is substantially perpendicular to the major surface of the ceramic dielectric body 10, the major axis of the amorphous filler 43 can be presumed to vary in the range of 3 to 60 μm. In this case, the maximum value of the major axis of the amorphous filler 43 can be presumed to be 60 μm.

TABLE 1
Variation of bonding agent thickness

| | | Bonding | Bonding | Bonding |
|---|---|---|---|---|
| | Spherical | agent | agent | agent average |
| | filler | thickest part | thinnest part | thickness |
| Test No. | addition | (μm) | (μm) | (μm) |
| 1 | none | 37 | 28 | 33 |
| 2 | none | 33 | 15 | 26 |
| 3 | none | 22 | 10 | 17 |
| 4 | none | 27 | 17 | 23 |
| 5 | none | 23 | 14 | 19 |
| 6 | none | 39 | 12 | 26 |
| 7 | none | 27 | 3 | 18 |
| 8 | none | 35 | 12 | 23 |
| 9 | none | 33 | 5 | 17 |
| 10 | none | 57 | 17 | 30 |
| 11 | none | 47 | 14 | 29 |
| 12 | none | 48 | 22 | 34 |
| 13 | none | 60 | 46 | 52 |
| 14 | none | 45 | 26 | 36 |
| 15 | none | 53 | 24 | 39 |
| 16 | none | 45 | 23 | 35 |
| 17 | none | 42 | 24 | 33 |
| 18 | none | 57 | 43 | 51 |
| 19 | none | 23 | 9 | 18 |
| 20 | none | 51 | 13 | 32 |
| 21 | none | 60 | 8 | 34 |
| 22 | none | 46 | 18 | 29 |
| 23 | none | 48 | 10 | 25 |
| 24 | none | 37 | 3 | 15 |
| 25 | none | 58 | 27 | 45 |
| 26 | none | 28 | 3 | 18 |
| | | 60 (maximum | 46 (maximum | |
| | | value) | value) | |
| | | 22 (minimum | 3 (minimum | |
| | | value) | value) | |

In actuality, when the electrostatic chuck was manufactured according to the manufacturing steps 1 to 5 described below, the generation of cracks was seen in the ceramic dielectric body 10 when using the bonding agent 40 in which only the amorphous filler 43 is blended and dispersed into the major agent 41.

The manufacturing process includes the following steps 1 to 5.

(1) First, the ceramic dielectric body 10, the ceramic substrate 20 and the temperature regulating unit 30 are manufactured independently.

(2) Next, the amorphous filler 43 is blended and dispersed into the major agent 41 of the bonding agent 40 and the spherical filler 42 is further blended and dispersed. The blending and dispersion is performed by a mixing machine.

(3) Next, the bonding agent 40 is applied to the respective bonding surfaces of the ceramic dielectric body 10 and the ceramic substrate 20 and the arrangement is placed into a vacuum chamber. The vacuum chamber is evacuated and the applied bonding agents 40 are brought together and vacuum bonded.

(4) Next, after the vacuum bonding, hot press curing is performed by a hot press curing machine. In this process, the thickness of the bonding agent 40 is appropriately adjusted. After the hot press curing, curing of the bonding agent 40 is performed in an oven.

(5) After the curing, the ceramic dielectric body 10 is ground to a predetermined thickness to form the adhesion face of the electrostatic chuck. For example, the ceramic dielectric body 10 may be ground to a prescribed thickness (1 mm), and then polished.

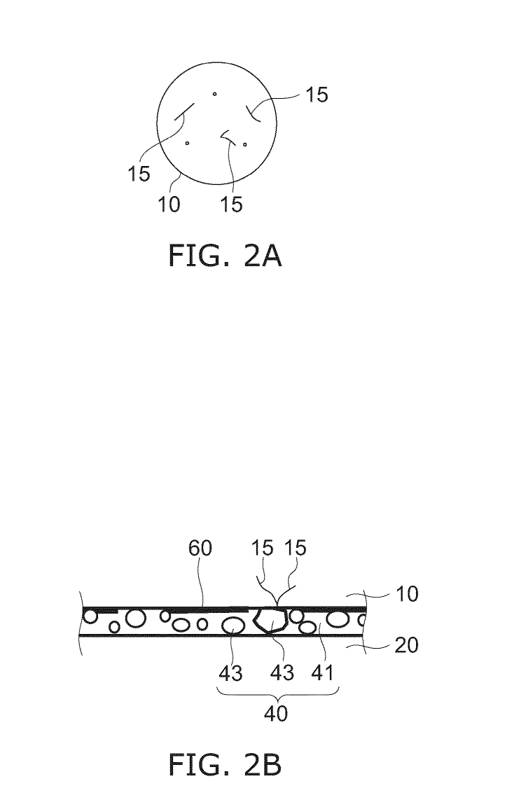

Generation of cracks in the ceramic dielectric body 10 was not observed immediately after completing thermosetting of the bonding agent 40. However, crack generation was observed when grinding the top surface of the ceramic dielectric body 10. For example, such a condition is illustrated in FIG. 2.

FIGS. 2A and 2B are schematic views of when crack generation has occurred in the ceramic dielectric body.

FIG. 2A is a schematic view of the top surface of the ceramic dielectric body 10 after the surface grinding process. As illustrated in the drawing, a crack 15 starts from the inner part of the ceramic dielectric body 10 and ends at the inner part of the ceramic dielectric body 10.

The cause of cracking is described below with reference to FIG. 2B.

As shown in FIG. 2B, when hot press curing is performed with the amorphous filler 43 that has a large size of approximately 60 μm interposed between the ceramic dielectric body 10 and the ceramic substrate 20, stress is concentrated in the area where the amorphous filler 43 contacts the ceramic dielectric body 10. It can be presumed that the crack 15 is generated with a starting point in this area.

However, when the average diameter of the spherical filler 42 is increased by 10 μm over the maximum value of the minor axis (60 μm) of the amorphous filler 43 to 70 μm, the spherical filler 42 contacts the ceramic substrate 20, the ceramic dielectric body 10 or the electrode 60 during hot press curing, and the above-described crack generation can therefore be suppressed.

For example, Table 2 shows the thickness results for the bonding agent 40 for when the spherical filler 42 and the amorphous filler 43 are blended and dispersed in the major agent 41. The average diameter of the spherical filler 42 is 70 μm.

A total of 4 samples, No. 31 to 34, were prepared as measurement samples. The variation in the thickness of the bonding agent 40 was found for these samples. Each sample was an arrangement configured by adhering together ceramic plates having a diameter of 300 mm using hot press curing with the bonding agent 40 in which the spherical filler 42 and the amorphous filler 43 were blended and dispersed into the major agent 41.

There is a total of 17 measurement points for each sample with 8 locations on the peripheral part, 8 locations in the intermediate part, and one location in the center part. The thickness of the thickest part, the thickness of the thinnest part, and the average thickness at 17 locations were found for each sample.

As shown in Table 2, the thickest part of the bonding agent 40 was kept within a range of 65 to 68 μm. The thinnest part of the bonding agent 40 was kept in a range of 57 to 61 μm. In other words, the results of Table 2 show a lower level of variation than the results of Table 1. In other words, it was found that the variation in the average thickness, the thickest part, and the thinnest part of the bonding agent 40 when blending and dispersing the spherical filler 42 was less than when the spherical filler 42 was not blended and dispersed. Further, it was found that the average thickness of the bonding agent 40 approximated to the average diameter (70 μm) of the spherical filler.

TABLE 2
Variation of bonding agent thickness

| | With | Bonding | Bonding | Bonding |
|---|---|---|---|---|
| | spherical | agent | agent | agent average |
| | filler | thickest part | thinnest part | thickness |
| Test No. | addition | (μm) | (μm) | (μm) |
| 31 | 70 (μm) | 67 | 61 | 64 |
| 32 | 70 (μm) | 65 | 61 | 62 |
| 33 | 70 (μm) | 65 | 57 | 63 |
| 34 | 70 (μm) | 68 | 60 | 64 |
| | | 68 (maximum | 61 (maximum | |
| | | value) | value) | |
| | | 65 (minimum | 57 (minimum | |
| | | value) | value) | |

In actuality, when the electrostatic chuck was manufactured using the manufacturing process including the above-described steps (1) through (5), the generation of cracks was not seen in the ceramic dielectric body 10 when using the bonding agent 40 in which the spherical filler 42 and the amorphous filler 43 are blended and dispersed into the major agent 41.

Thus, when the average diameter of the spherical filler 42 is greater than the maximum value of a minor axis of all of the amorphous filler 43, the spherical filler 42 can be used to set the thickness of the bonding agent 40 to be equal to or greater than the average diameter of the spherical filler 42. As a result, crack generation in the ceramic dielectric body 10 can be prevented during hot press curing of the bonding agent 40, and it becomes less likely that local stress will be applied to the ceramic dielectric body 10 by the amorphous filler 43.

Further, in this embodiment, the average diameter of the spherical filler 42 is configured to be at least 10 μm greater than the maximum value of the minor axis of the amorphous filler 43. When the average diameter of the spherical filler 42 is at least 10 μm greater than the maximum value of the minor axis of the amorphous filler 43, the thickness of the bonding agent 40 can be controlled by the average diameter of the spherical filler 42 and not by the size of the amorphous filler 43 at the time of hot press curing the bonding agent 40. In other words, at the time of hot press curing, it is less likely that local stress will be applied to the ceramic substrate 20 and the ceramic dielectric body 10 by the first amorphous filler 43. Accordingly, the crack generation in the ceramic dielectric body 10 can be prevented.

Further, when the variation in the flatness and thickness of the ceramic substrate and the ceramic dielectric body positioned above and below the first bonding agent is not more than 10 μm (for example, 5 μm), the surface irregularity of the ceramic substrate and the ceramic dielectric body can be absorbed (mitigated) by the bonding agent 40 through setting the average diameter of the first spherical filler to be at least 10 μm greater than the maximum value of the minor axis of the first amorphous filler. Further, when the variation in the flatness and thickness of the electrode 60 provided on the surface of the ceramic substrate 20 is not more than 10 μm (for example, 5 μm), the surface irregularity of the electrode 60 can be absorbed (mitigated) by the bonding agent 40 through setting the average diameter of the spherical filler 42 to be at least 10 μm greater than the maximum value of the minor axis of the amorphous filler 43. In this case, the spherical filler 42 will contact the surface of the electrode 60 without contacting the ceramic substrate 20 or the ceramic dielectric body 10. Therefore, crack generation in the ceramic dielectric body 10 can be suppressed.

Further, for the bonding agent 50 between the ceramic substrate 20 and the temperature regulating unit 30, the average diameter of the spherical filler 52 is also set to be greater than the maximum value of a minor axis of all of the amorphous filler 53. Therefore, as a result of the spherical filler 52, the thickness of the bonding agent 50 can be controlled to be either equal to or greater than the average diameter of the spherical filler 52. Accordingly, local stress is not applied to the ceramic substrate 20 by the amorphous filler 53 during hot press curing of the bonding agent 50, and crack generation in the ceramic substrate 20 can be prevented.

Further, the rigidity of the ceramic substrate 20 is increased by the existence of the temperature regulating unit 30 on the bottom side of the ceramic substrate 20. Also, when the ceramic dielectric body 10 is processed, crack generation in the ceramic dielectric body 10 can be prevented. Dispersion-compounding the spherical filler 52 into the bonding agent 50 makes it possible to fixedly hold the ceramic substrate 20 at a uniform thickness. As a result, damage to the ceramic dielectric body 10 can be avoided even when processing the ceramic dielectric body 10.

Further, when the temperature regulating unit 30 is made of metal, the linear expansion coefficient of the temperature regulating unit 30 will be greater than the linear expansion coefficient of the ceramic substrate 20. By setting the average diameter of the spherical filler 52 to be greater than the average diameter of the spherical filler 42, the thickness of the bonding agent 50 is caused to be greater than the thickness of the bonding agent 40. Accordingly, the difference in thermal contraction and expansion between the ceramic substrate 20 and the temperature regulating unit 30 can be easily absorbed within the bonding agent 50. As a result, deformation of the ceramic substrate 20 and separation of the ceramic substrate 20 and the temperature regulating unit 30 are less likely to occur.

Next, the blending quantities of the spherical filler 42 in the bonding agent 40 were verified, and are thus described below. The bonding agent 40 is prepared containing 80 wt % amorphous filler 43.

Table 3 shows the blending quantity test results for the spherical filler 42. In this test, a volume concentration of the spherical filler 42 that could be blended and dispersed within the bonding agent 40 containing the amorphous filler 43 was verified.

First, when the volume concentration of the spherical filler 42 was not more than 0.020 vol %, the thickness of the bonding agent 40 was smaller, and cracks were generated in the spherical filler 42 or the ceramic dielectric body 10. The cause of this was presumed to be a localized concentration of press pressure on the spherical filler 42 or the ceramic dielectric body 10 that touches the spherical filler 42 during hot press curing. Conversely, when the volume concentration of the spherical filler 42 is greater than 0.020 vol %, dispersion of the spherical filler 42 within the bonding agent 40 is favorable. In other words, the spherical filler 42 is spread evenly within the bonding agent 40, making it less likely that localized pressure will be applied to the ceramic dielectric body 10 by the amorphous filler 43. Therefore, crack generation in the ceramic dielectric body 10 is suppressed.

Further, it was discovered that when the volume concentration of the spherical filler 42 was not less than 46.385 vol %, the spherical filler 42 was not sufficiently dispersed within the bonding agent 40. As long as the volume concentration (vol %) of the spherical filler 42 is less than 42.0 vol %, dispersion of the spherical filler 42 will be uniform within the bonding agent 40 containing the amorphous filler 43.

Thus, it is preferable that the volume concentration of the spherical filler 42 is greater than 0.025 vol % and less than 42.0 vol % relative to the bonding agent 40 containing the amorphous filler 43.

TABLE 3
Blending quantity test results

| Spherical filler | Spherical filler | Adhesion | |
|---|---|---|---|
| type | quantity (vol %) | possibility | Remarks |
| glass | 0.008% | No | bonding agent |
| | | | thickness small |
| | | | (poor press |
| | | | thickness) |
| glass | 0.016% | No | bonding agent |
| | | | thickness small |
| | | | (poor press |
| | | | thickness) |
| glass | 0.020% | No | partially poor |
| | | | bonding agent |
| | | | thickness |
| glass | 0.030% | Yes | |
| glass | 0.040% | Yes | |
| glass | 0.099% | Yes | |
| glass | 0.199% | Yes | |
| glass | 0.398% | Yes | |
| glass | 0.586% | Yes | |
| glass | 1.992% | Yes | |
| glass | 7.116% | Yes | uniform bonding |
| | | | agent thickness |
| glass | 34.627% | Yes | uniform bonding |
| | | | agent thickness |
| glass | 41.300% | Yes | uniform bonding |
| | | | agent thickness |
| glass | 46.385% | No | unable stirring |
| | | | of bonding agent |
| | | | and filler |
| Glass(2) | 0.178% | Yes | |
| Glass(2) | 0.357% | Yes | |
| Glass(2) | 0.722% | Yes | |
| alumina | 0.026% | Yes | |
| alumina | 0.052% | Yes | |
| alumina | 0.103% | Yes | |

Glass compressive strength: 832 MPa, glass (2) compressive strength: 466 MPa. Alumina compressive strength: 3200 MPa, “Yes”: Adhesion successful, “No”: Adhesion not successful

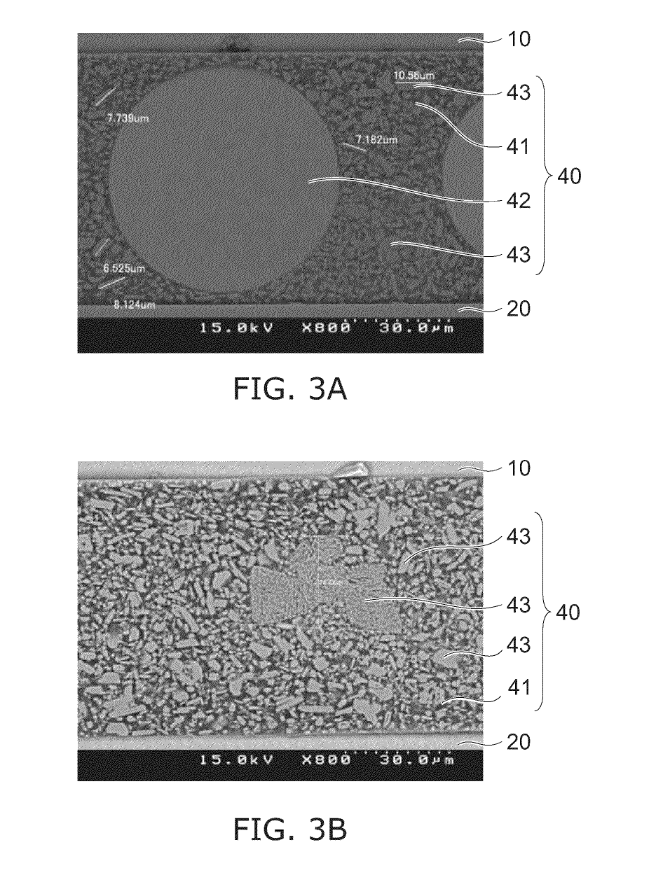

FIGS. 3A and 3B are cross-sectional SEM images of the bonding agents, FIG. 3A being a cross-sectional SEM image of the bonding agent in which the spherical filler and the amorphous filler are blended and dispersed, and FIG. 3B being a cross-sectional SEM image of the bonding agent in which the amorphous filler is blended and dispersed. The field of view of the cross-sectional SEM images is at 800× magnification.

In the bonding agent 40 shown in FIG. 3A, the spherical filler 42 and the amorphous filler 43 are blended and dispersed. The ceramic dielectric body 10 and the ceramic substrate 20 are observed above and below the bonding agent 40. In this SEM image, the spherical filler 42 does not reach the bottom face of the ceramic dielectric body 10 or the top face of the ceramic substrate 20. This is because the spherical filler 42 has been sectioned at a position in front of (or deeper than) the position of the maximum diameter. The diameter of the spherical filler 42 is approximately 70 μm.

In the bonding agent 40 shown in FIG. 3B, the spherical filler 42 has not been dispersed. Thus, only the major agent 41 and the amorphous filler 43 are observed between the ceramic dielectric body 10 and the ceramic substrate 20. The results for the maximum value of the minor axis of the amorphous filler 43 from the cross-sectional SEM images are shown in Table 4.

TABLE 4
Maximum value of minor axis of amorphous filler

| | Amorphous filler minor |
|---|---|
| SEM image No. | axis maximum value |
| 1 | 10.56 μm |
| 2 | 12.26 μm |
| 3 | 11.95 μm |
| 4 | 10.09 μm |
| 5 | 15.87 μm |
| 6 | 13.06 μm |
| 6 | 10.40 μm |
| 8 | 11.07 μm |
| 9 | 16.20 μm |
| 10 | 11.58 μm |
| 11 | 13.20 μm |
| 12 | 26.73 μm |
| 13 | 15.75 μm |
| 14 | 9.73 μm |
| 15 | 15.42 μm |
| 16 | 11.27 μm |

From Table 4, the maximum values of the minor axis of the amorphous filler 43 vary in a range of 9.73 μm to 26.73 μm. Because the average diameter of the spherical filler 42 is 70 μm, it is understood that the average diameter of the spherical filler is greater than a maximum value of a minor axis of all of the amorphous filler 43.

Note that FIG. 4 is a diagram for describing the minor axis of the amorphous filler.

The minor axis of the amorphous filler 43 is the length of the short direction that is orthogonal to the longitudinal direction (arrow C) of the amorphous filler 43. For example, this corresponds to d1, d2, d3, and the like in the drawing. The maximum value of the minor axis is the largest minor axis value from among the plurality of all the amorphous filler 43.

In addition, in this embodiment, the thermal conductivities of the spherical filler 42 and the amorphous filler 43 are greater than the thermal conductivity of the major agent 41 of the bonding agent 40. Because the thermal conductivities of the spherical filler 42 and the amorphous filler 43 are greater than the major agent 41 of the bonding agent 40, the thermal conductivity of the bonding agent 40 is greater than that of a bonding agent with only the major agent, and the cooling properties of the electrostatic chuck are thus improved.

The thermal conductivity of the spherical filler 42 (glass) is less than the thermal conductivity of the amorphous filler 43 (alumina). For example, if the spherical filler 42 contacts the ceramic substrate 20, the ceramic dielectric body 10, or the electrode 60 provided on the ceramic dielectric body 10, the fact that the thermal conductivity of the spherical filler 42 (glass) is less than the thermal conductivity of the amorphous filler 43 (alumina or the like) means that the difference in thermal conductivity between portions contacting the spherical filler 42 and other portions will be reduced. Accordingly, uniformity can be promoted in the in-plane temperature distribution of the ceramic dielectric body 10.

Further, the thickness of the ceramic dielectric body 10 is equal to or greater than the thickness of the ceramic substrate 20. Making the thickness of the ceramic dielectric body 10 equal to or less than the thickness of the ceramic substrate 20 allows the ceramic dielectric body 10 to be reliably and fixedly held on the ceramic substrate 20. Accordingly, when the ceramic dielectric body 10 and the ceramic substrate 20 have been bonded, crack generation in the ceramic dielectric body 10 can be prevented, even when the ceramic dielectric body 10 is processed. Moreover, the flatness and uniformity of the thickness of the ceramic dielectric body 10 after processing is favorable.

Further, FIGS. 5A and 5B are diagrams for describing one example of effects of the electrostatic chuck. FIG. 5A shows a cross-sectional schematic view of the electrostatic chuck 1, and FIG. 5B shows a comparative example.

Because the spherical filler 42 is spherically shaped, the amorphous filler 43 slides more easily on account of the curved surface of the spherical filler 42 when the spherical filler 42 is being pressed on the ceramic dielectric body 10 side, even if large amorphous filler 43 exists between the ceramic dielectric body 10 and the spherical filler 42. Hence, in the electrostatic chuck 1, the amorphous filler 43 is less likely to remain between the spherical filler 42 and the ceramic dielectric body 10.

By contrast, in the comparative example, because a cylindrical filler 420 with a rectangular profile is used, the amorphous filler 43 is easily held between the cylindrical filler 420 and the ceramic dielectric body 10. Therefore, in a comparative example, the amorphous filler 43 is likely to remain between the cylindrical filler 420 and the ceramic dielectric body 10. Thus, as described in this embodiment, use of the spherical filler 42 is preferred. Note that a similar effect can be obtained when the spherical filler 42 is replaced by the spherical filler 52.

The invention has been described with reference to the embodiments. However, the invention is not limited to these descriptions. Those skilled in the art can suitably modify the above embodiments by design change, and such modifications are also encompassed within the scope of the invention as long as they include the feature of the invention. For example, the shape, dimension, materials and disposal of components are not limited to those illustrated, and can be suitably modified.

Components of the embodiments described above can be combined and multiple as long as technically possible, and such combinations can be encompassed within the scope of the invention as long as they include the feature of the invention.

### INDUSTRIAL APPLICABILITY

Used as an electrostatic chuck for clamping a processing target substrate.

### REFERENCE SIGNS LIST

1 electrostatic chuck

10 ceramic dielectric body

15 crack

20 ceramic substrte

30 temperature regulating unit

30t media path

40, 50 bonding agent

41, 51 major agent

42, 52 spherical filler

43, 53 amorphous filler

60 electrode

1. An electrostatic chuck comprising:
a ceramic dielectric body having an electrode formed on a surface of the ceramic dielectric body;
a ceramic substrate supporting the ceramic dielectric body; and
a first bonding agent bonding the ceramic dielectric body to the ceramic substrate,
the first bonding agent having a first major agent including an organic material, a first amorphous filler including an inorganic material, and a first spherical filler including an inorganic material,
the first amorphous filler and the first spherical filler being dispersion-compounded in the first major agent,
the first major agent, the first amorphous filler, and the first spherical filler being made of an electrically insulating material,
an average diameter of the first spherical filler being greater than a maximum value of a minor axis of all of the first amorphous filler, and
a thickness of the first bonding agent being equal to or greater than the average diameter of the first spherical filler.

2. The electrostatic chuck according to claim 1, wherein the average diameter of the first spherical filler is at least 10 μm greater than the maximum value of the minor axis of the first amorphous filler.

3. The electrostatic chuck according to claim 1, wherein a volume concentration (vol %) of the first spherical filler is greater than 0.025 vol % and less than 42.0 vol % relative to a volume of the first bonding agent containing the first amorphous filler.

4. The electrostatic chuck according to claim 1, wherein a material of the first major agent of the first bonding agent is one of a silicon resin, an epoxy resin, or a fluororesin.

5. The electrostatic chuck according to claim 1, wherein a thermal conductivity of the first spherical filler and a thermal conductivity of the first amorphous filler are higher than a thermal conductivity of the first major agent of the first bonding agent.

6. The electrostatic chuck according to claim 1, wherein a material of the first spherical filler and a material of the first amorphous filler are different.

7. The electrostatic chuck according to claim 5, wherein the thermal conductivity of the first spherical filler is lower than the thermal conductivity of the first amorphous filler.

8. The electrostatic chuck according to claim 7, wherein the thermal conductivity of the first spherical filler is equal to or lower than the thermal conductivity of a mixture of the first amorphous filler and the first major agent.

9. The electrostatic chuck according to claim 8, wherein the thermal conductivity of the first spherical filler is in a range from 0.4 times to 1.0 times the thermal conductivity of the mixture of the first amorphous filler and the first major agent.

10. The electrostatic chuck according to claim 1, wherein a thickness of the ceramic dielectric body is equal to or less than a thickness of the ceramic substrate.

11. The electrostatic chuck according to claim 10, wherein a Vickers hardness of the first spherical filler is less than a Vickers hardness of the ceramic dielectric body.

12. The electrostatic chuck according to claim 1, further comprising a temperature regulating unit bonded to the ceramic substrate; and
a second bonding agent bonding the ceramic substrate to the temperature regulating unit,
the second bonding agent having a second major agent including an organic material, a second amorphous filler including an inorganic material, and a second spherical filler including an inorganic material,
the second amorphous filler and the second spherical filler being dispersion-compounded in the second major agent,
the second major agent, the second amorphous filler, and the second spherical filler being made of the electrically insulating material,
an average diameter of the second spherical filler being greater than a maximum value of a minor axis of all of the second amorphous filler;
a thickness of the second bonding agent is equal to or greater than the average diameter of the second spherical filler, and
the average diameter of the second spherical filler is greater than the average diameter of the first spherical filler.
